(19) United States
(12) Patent Application Publication
(10) Pub. No.: US 2023/0027120 A1
(43) Pub. Date: Jan. 26, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shao-Tzu Tang, Taichung City (TW); Wen-Jung Tsai, Taichung City (TW); Chih-Hsien Chiu, Taichung City (TW); Ko-Wei Chang, Taichung City (TW); Yu-Wei Yeh, Taichung City (TW); Yu-Cheng Pai, Taichung City (TW); Chuan-Yi Pan, Taichung City (TW); Chi-Rui Wu, Taichung City (TW)

(73) Assignee: SILICONWARE PRECISION INDUSTRIES CO., LTD., Taichung City (TW)

(21) Appl. No.: 17/411,322

(22) Filed: Aug. 25, 2021

(30) Foreign Application Priority Data
Jul. 21, 2021 (TW) 110126820

(51) Int. Cl. H01Q 1/22; H01L 23/552

(52) U.S. Cl. CPC H01Q 1/2283; H01L 23/552

(57) ABSTRACT

An electronic package is provided, in which a carrier structure provided with electronic components is disposed onto an antenna structure, where a stepped portion is formed at an edge of the antenna structure, so that a shielding body is arranged along a surface of the stepped portion. Therefore, the shielding body only covers a part of the surface of the antenna structure to prevent the shielding body from interfering with operation of the antenna structure.

### BACKGROUND

### 1. Technical Field

The present disclosure relates to a semiconductor packaging process, and more particularly, to an electronic package with shielding mechanism and manufacturing method thereof.

### 2. Description of Related Art

With the prosperous development of semiconductor technology, various forms of packaging product for semiconductor products are developed, in which various semiconductor products (e.g., radio-frequency modules) with shielding functionalities are present to prevent problems of electromagnetic interference (EMI) and to enhance electronic quality.

Referring to FIGS. 1A and 1B, a conventional radio-frequency (RF) module 1 is shown, where a plurality of RF chips 11 are electrically connected to a package substrate 10 having an antenna layer 12, an encapsulant 13 encapsulates each of the RF chips 11, and a metal shielding layer 14 is formed on a top surface 13a and side surfaces 13c of the encapsulant 13 and side surfaces 10c of the package substrate 10. Therefore, the metal shielding layer 14 protects the RF chips 11 from impact of EMI from the outside.

However, in the conventional RF module 1, due to the metal shielding layer 14 covering the side surfaces 10c of the package substrate 10, the metal shielding layer 14 shields the antenna layer 12, thus prevents the antenna functionality of the antenna layer 12 from properly operating.

Therefore, how to overcome the various problems of the above-mentioned prior art has become an urgent problem to be solved at present.

### SUMMARY

In view of the aforementioned shortcomings of the prior art, the present disclosure provides an electronic package, which comprises: a carrier structure; an electronic component disposed on the carrier structure; an antenna structure mounted on the carrier structure, wherein the antenna structure has an edge formed with a stepped portion; and a shielding body arranged along a surface of the stepped portion.

The present disclosure further provides a method for manufacturing the electronic package, which comprises: providing at least one package module, wherein the package module comprises a carrier structure and an electronic component disposed on the carrier structure; and connecting an antenna structure to the carrier structure, wherein the antenna structure has an edge formed with a stepped portion, and wherein a shielding body is arranged on a surface of the stepped portion.

In the aforementioned electronic package and method, the carrier structure is coupled to the antenna structure via a plurality of conductive components.

In the aforementioned electronic package and method, the antenna structure has a first surface, a second surface opposite to the first surface, and a side surface abutting the first and second surfaces, wherein the first surface of the antenna structure is connected to the carrier structure. For example, the stepped portion is formed at an interface between the first surface and the side surface. Alternatively, the stepped portion is formed at an interface between the second surface and the side surface.

In the aforementioned electronic package and method, the present disclosure further comprises encapsulating the electronic component via an encapsulation layer, and forming a shielding layer on the encapsulation layer.

In the aforementioned electronic package and method, the shielding body is a metal layer.

As should be understood from the electronic package and manufacturing method thereof above, the present disclosure utilizes the stepped portion formed on edges of the antenna structure to enable the shielding body to cover a part of a surface of the antenna structure only so as to prevent the shielding body from interfering operation of the antenna structure. Therefore, compared to the prior art, the electronic package of the present disclosure may effectively operate the antenna functionality of the antenna structure.

### BRIEF DESCRIPTION OF THE DRAWINGS

FIG. 1A is a schematic cross-sectional view of a conventional radio-frequency (RF) module.

FIG. 1B is a schematic three-dimensional view of the conventional RF module.

FIGS. 2A to 2E and 2F-1 are schematic cross-sectional views illustrating a method for manufacturing an electronic package according to the present disclosure.

FIGS. 2F-2 and 2F-3 are schematic cross-sectional views depicting other aspects of FIG. 2F-1.

FIGS. 3A to 3C are schematic cross-sectional views illustrating another manufacturing method for the manufacturing method of FIGS. 2D to 2F-1.

FIGS. 4A to 4D are schematic cross-sectional views illustrating a manufacturing method for the antenna module shown in FIG. 2D.

FIGS. 5A to 5C are schematic cross-sectional views depicting other embodiments of the electronic package according to the present disclosure.

### DETAILED DESCRIPTION OF THE EMBODIMENTS

Implementations of the present disclosure are illustrated using the following embodiments. One of ordinary skill in the art can readily appreciate other advantages and technical effects of the present disclosure upon reading the content of this specification.

It should be noted that the structures, ratios, sizes shown in the drawings appended to this specification are to be construed in conjunction with the disclosure of this specification in order to facilitate reading and understanding of those skilled in the art. They are not meant, in any ways, to limit the implementations of the present disclosure, and therefore have no substantial technical meaning. Any modifications, changes or adjustments to the structures, ratio relationships or sizes, are to be construed as falling within the range covered by the technical contents disclosed herein to the extent of not causing changes in the technical effects created and the objectives achieved by the present disclosure, meanwhile, terms such as “above,” “first,” “second,” “a,” “an,” and the like recited herein are for illustrative purposes, and are not meant to limit the scope in which the present disclosure can be implemented. Any variations or modifications to their relative relationships, without changes in the substantial technical content, should also be regarded as within the scope in which the present disclosure can be implemented.

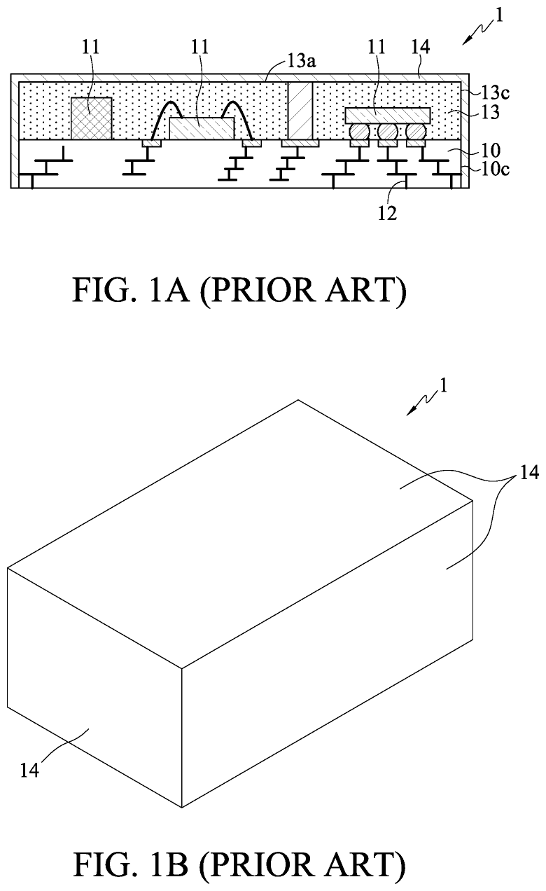

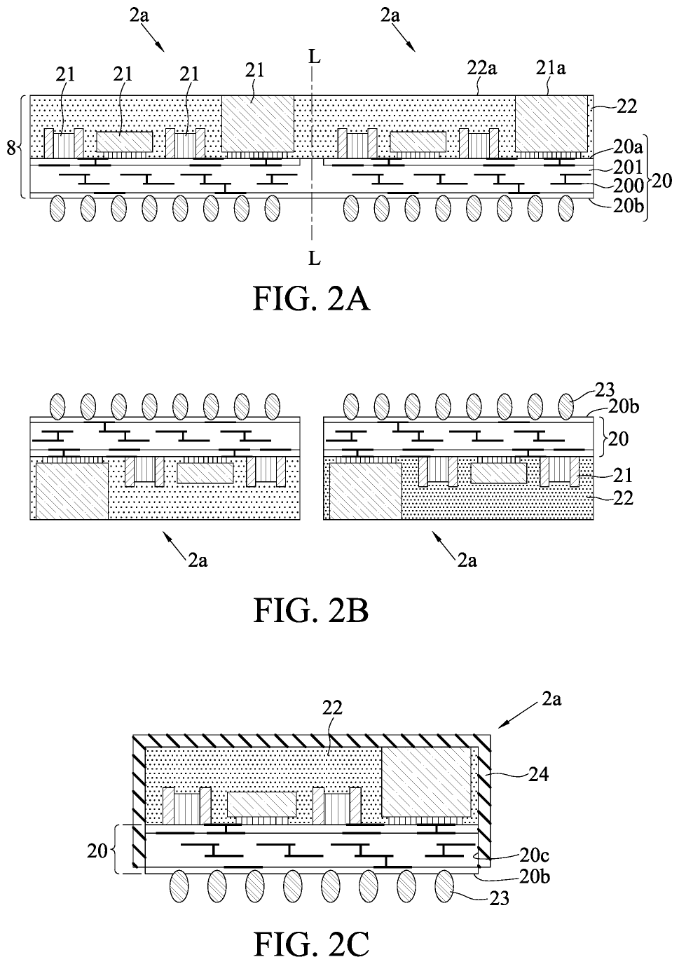

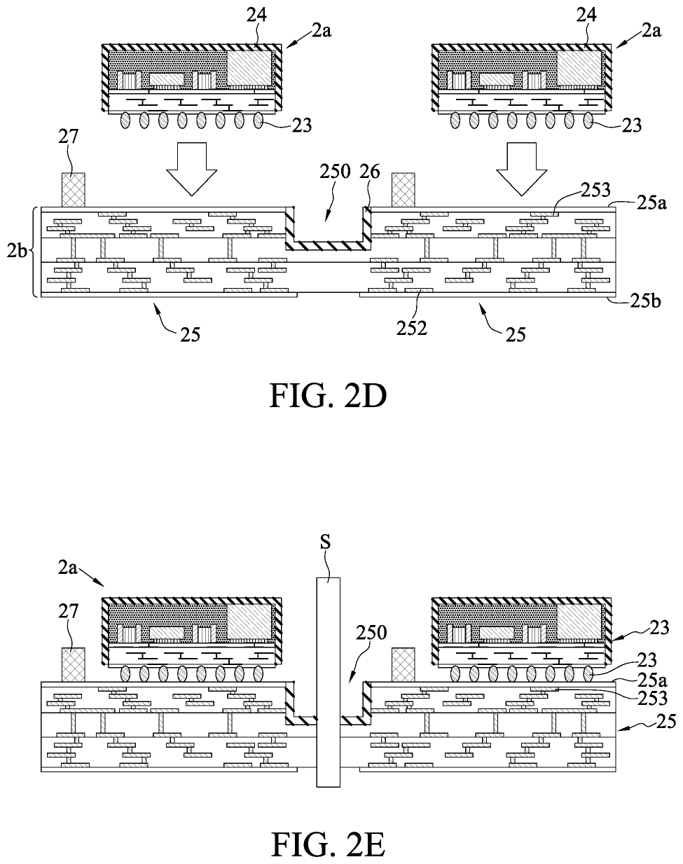

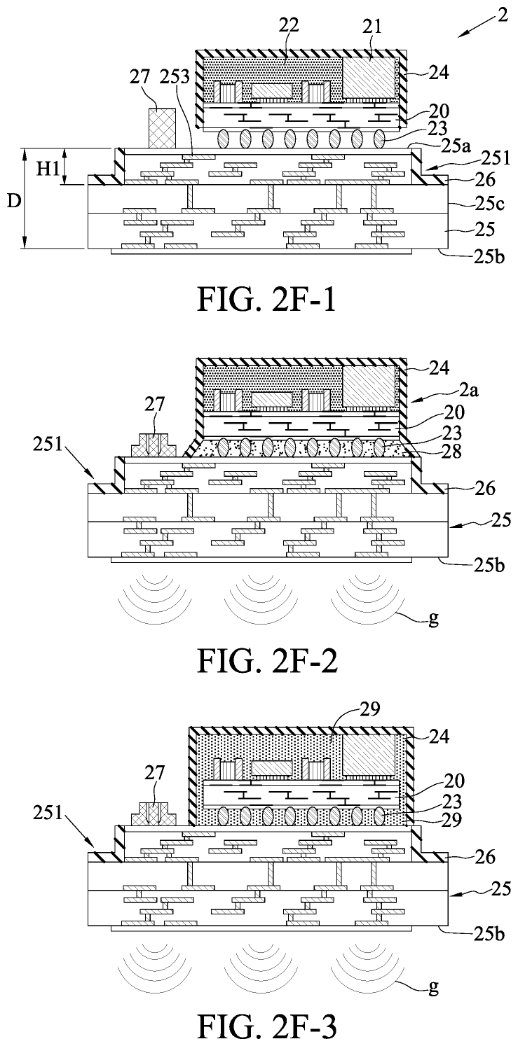

FIGS. 2A to 2F-1 are schematic cross-sectional views illustrating a method for manufacturing an electronic package 2 according to the present disclosure.

As shown in FIG. 2A, a full-plate package body 8 comprising a plurality of package modules 2a is provided. The package modules 2a comprise a carrier structure 20, a plurality of electronic components 21 provided on the carrier structure 20, and an encapsulation layer 22 provided on the carrier structure 20 for encapsulating the electronic components 21.

The carrier structure 20 is, for example, a package substrate having a core layer and circuit structure or a coreless circuit structure, which has a plurality of circuit layers 200 (such as fan-out redistribution layers [RDLs]) formed on an insulating material 201.

In an embodiment, the carrier structure 20 comprises a first side 20a and a second side 20b opposite to the first side 20a. The material forming the circuit layers 200 is copper. The insulating material 201 is a dielectric material such as polybenzoxazole (PBO), polyimide (PI), prepreg (PP), or the like, or solder-proof material such as solder mask or solder resist.

The electronic components 21 are provided on the first side 20a of the carrier structure 20. The electronic components 21 are active components such as semiconductor chips, passive components such as resistors, capacitors, or inductors, or a combination of active and passive components.

In an embodiment, the electronic components 21 may electrically connect to the circuit layers 200 of the carrier structure 20 via flip-chip manner, wire-bonding manner, direct contacting the circuit layers 200, or other suitable manners, of which the present disclosure is not limited thereto.

The encapsulation layer 22 is provided on the first side 20a of the carrier structure 20 to encapsulate the electronic components 21.

In an embodiment, the encapsulation layer 22 is an insulation material such as a polyimide (PI), a dry film, an encapsulant such as epoxy resin, or a molding compound, of which the present disclosure is not limited thereto.

Further, a planarization process may be utilized to expose a surface 21a of at least one of the electronic components 21 from a surface 22a of the encapsulation layer 22 so as to enable the surface 22a of the encapsulation layer 22 flush with the surface 21a of the electronic component 21. For example, the planarization process may remove a portion of the electronic components 21 and a portion of the encapsulation layer 22 via polishing.

As shown in FIG. 2B, a plurality of conductive components 23 are formed on the second side 20b of the carrier structure 20. A singulation process is then performed along a cutting path L shown in FIG. 2A on the full-plate package body 8 so as to obtain a plurality of package modules 2a separated from one another.

In an embodiment, the conductive components 23 have shapes of balls like solder balls, pillars like copper pillars or solder bumps, or stud conductors made by wire bonder, of which the present disclosure is not limited thereto.

As shown in FIG. 2C, a shielding layer 24 is formed on an outer surface of each of the package modules 2a, where the shielding layer 24 is free from contacting the conductive components 23.

In an embodiment, the shielding layer 24 is formed on the encapsulation layer 22 and extended to the side surfaces 20c of the carrier structure 20, and the shielding layer 24 is free from being formed on the second side 20b of the carrier structure 20.

Further, the shielding layer 24, such as a metal layer, is manufactured through means such as sputtering, evaporation, electroplating, electroless plating or filming, of which the present disclosure is not limited thereto.

As shown in FIG. 2D, a full-plate antenna module 2b is provided, which comprises a plurality of antenna structures 25. Further, at least one concave portion 250 is formed at an interface between two of the antenna structures 25, and a shielding body 26 (such as a metal layer) is formed along a surface of the concave portion 250.

In an embodiment, the antenna structure 25 is, for example, a package substrate having a core layer and circuit structure or a coreless circuit structure, which comprises a first surface 25a and a second surface 25b opposing the first surface 25a. For example, the antenna structure 25 is an antenna substrate having at least one antenna main layer 252 formed on an inner dielectric material, and a plurality of contacts 253 are formed on the first surface 25a of the antenna structure 25, where the second surface 25b is served as an emission/receive surface for the antenna main layer 252.

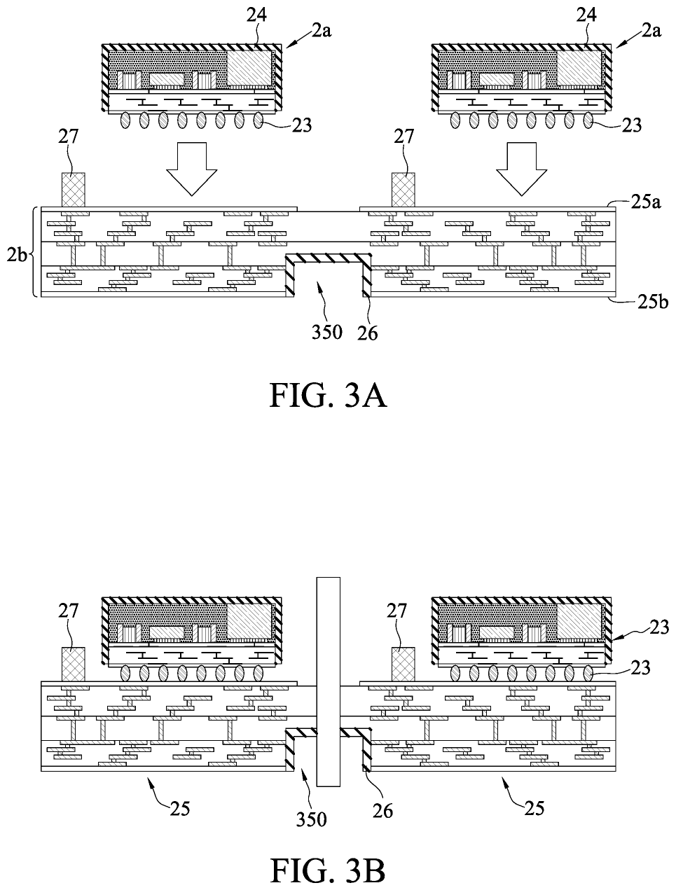

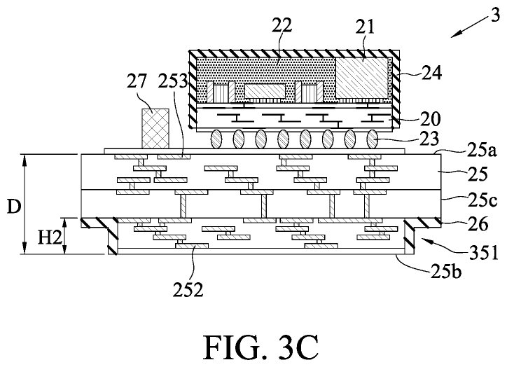

Further, the concave portion 250 is formed at an interface between the first surfaces 25a of two of the antenna structures 25; or, as shown in FIG. 3A, the concave portion 350 is formed at an interface between the second surfaces 25b of two of the antenna structures 25.

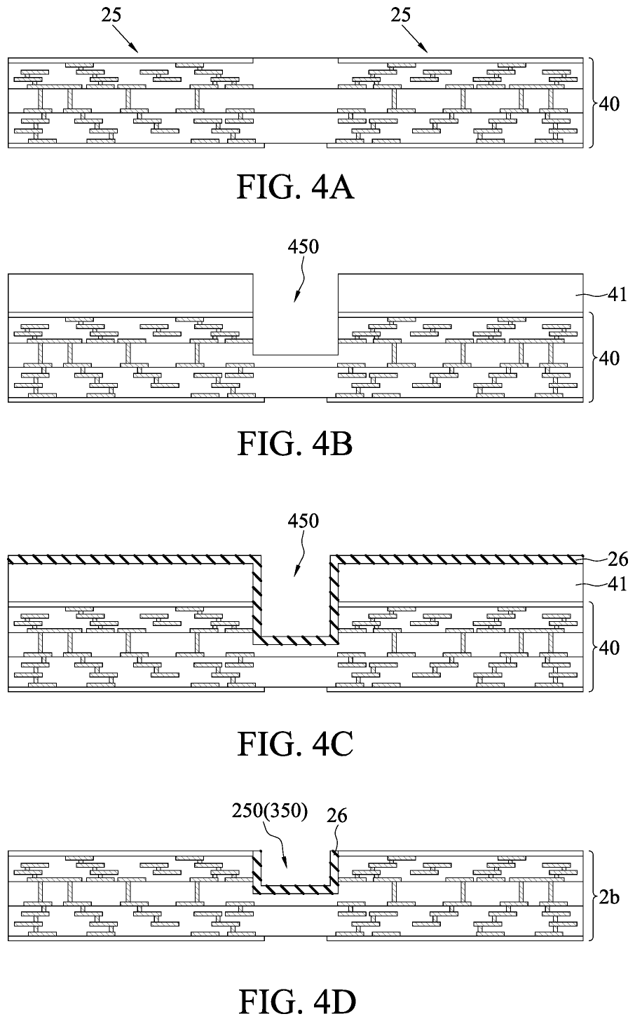

Moreover, manufacturing process for the antenna module 2b is shown in FIGS. 4A to 4D. As shown in FIG. 4A, a full-plate circuit structure 40 having a plurality of antenna structures 25 is provided. Then, as shown in FIG. 4B, a barrier layer 41 is formed on the circuit structure 40, and a concave portion 450 extending to the circuit structure 40 is formed on the barrier layer 41. Then, as shown in FIG. 4C, a shielding body 26, such as a metal layer, is formed on the barrier layer 41 and extend along a surface of the concave portion 450 through means such as sputtering, evaporation, electroplating, electroless plating or filming. Lastly, as shown in FIG. 4D, the barrier layer 41 and the shielding body 26 on the barrier layer 41 are removed, and the shielding body 26 on the concave portions 250, 350 of the antenna structure 25 is remained.

In addition, the antenna module 2b may arrange related components, such as a connector 27, on the first surface 25a of the antenna structure 25 according to requirements. As should be understood therefrom, the antenna module 2b varies in type, and thus is not limited thereto.

As shown in FIG. 2E, which is a continuation in manufacturing process of FIG. 2D, the plurality of package modules 2a are mounted onto contacts 253 of the first surface 25a of the antenna structures 25 of the antenna module 2b via the conductive components 23, such that the carrier structure 20 is electrically connected to the antenna structures 25 via the conductive components 23.

As shown in FIG. 2F-1, a singulation process is performed along a cutting path S (i.e., corresponding to the concave portion 250) on the antenna module 2b shown in FIG. 2E so as to obtain a plurality of electronic packages 2, where the antenna structure 25 defines the side surfaces 25c that abut the first surface 25a and the second surface 25b.

In an embodiment, the interface between the first surface 25a and the side surface 25c of the antenna structure 25 is formed with a stepped portion 251, with the shielding body 26 arranged along a surface of the stepped portion 251, thus making the antenna structure 25 to appear notched (e.g., to appear as L shaped from side view) at its edges. Therefore, the side surface 25c corresponding to emission end (the second surface 25b) of the antenna structure 25 is free of shielding mechanism, while the side surface corresponding to signal transmission circuit (the contacts 253 on the first surface 25a) is configured with shielding mechanism. For example, a length H1 of the stepped portion 251 at the side surface 25c is ⅓ to ⅔ of a length D of the side surface 25c.

Further, the package module 2a varies in type, and is not limited thereto. As shown in FIG. 2F-2, the package module 2a may comprise an underfill 28 that fills the space between the carrier structure 20 and the antenna structure 25 after the package module 2a is mounted on the antenna structure 25 via the conductive components 23, such that the underfill 28 may encapsulate the conductive components 23, where the second surface 25b of the antenna structure 25 is an emission end configured to emit signal g. Alternatively, as shown in FIG. 2F-3, the package module 2a is mounted on the antenna structure 25 before the encapsulation layer 29 and the shielding layer 24 are formed, such that the encapsulation layer 22 may fill the space between the carrier structure 20 and the antenna structure 25 so as to encapsulate the conductive components 23, where the second surface 25b of the antenna structure 25 is an emission end configured to emit signal g.

Moreover, if continue with the manufacturing process shown in FIG. 3A (i.e., providing the concave portion 350 on the second surface 25b of the antenna structure 25), a singulation process is performed on the antenna module 2b along a cutting path S (i.e., corresponding to the concave portion 350) shown in FIG. 3B so as to obtain a plurality of electronic packages 3 as shown in FIG. 3C, with an interface between the second surface 25b and the side surface 25c of the antenna structure 25 is formed with a stepped portion 351. The shielding body 26 is arranged along the surface of the stepped portion 351, thus making the second surface 25b of the antenna structure 25 to appear notched at its edges, and making the side surface 25c corresponding to the emission end (the second surface 25b) of the antenna structure 25 configured with shielding mechanism, while the side surface corresponding to the signal transmission circuit (the contacts 253 on the first surface 25a) is free of shielding mechanism. For example, a length H2 of the stepped portion 351 at the side surface 25c is ⅓ to ⅔ of the length D of the side surface 25c, such that the antenna structure 25 may emit signals from the second surface 25b and a part of the side surfaces 25c of the antenna structure 25, and not impacted by the shielding body 26 with respect to emission direction.

Therefore, the manufacturing method of the present disclosure prevents the shielding body 26 from interfering the receive and emission of the antenna main layer 252 of the antenna structure 25 via forming stepped portion 251, 351 at edges of the antenna structure 25 and making the shielding body 26 covers a part of the side surfaces 25c of the antenna structure 25 only. Therefore, compared to the prior art, the electronic package 2, 3 of the present disclosure may effectively operate the antenna functionality of the antenna structure 25.

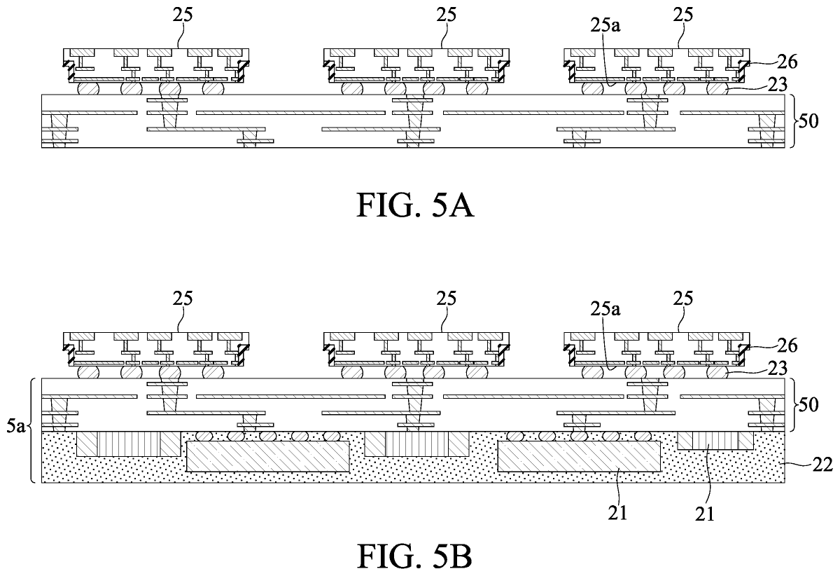

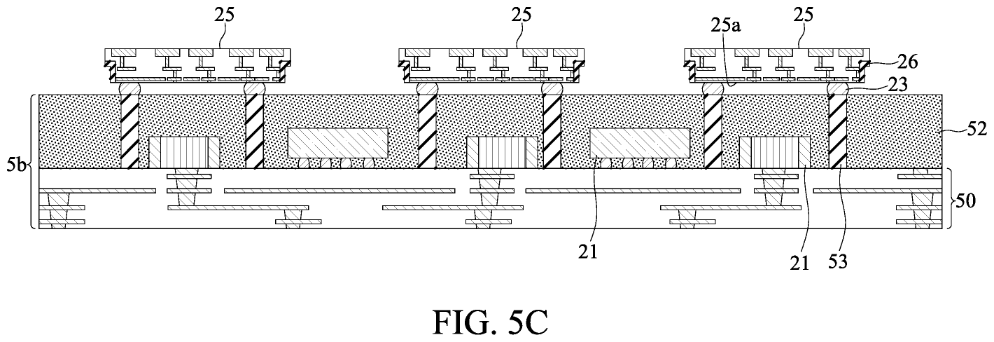

Additionally, the antenna structure 25 having the shielding body 26 may be applied in various types of semiconductor packaging processes. For example, as shown in FIG. 5A, a plurality of antenna structures 25 having the shielding body 26 are mounted onto a carrier structure 50 such as a circuit board or substrate via a plurality of conductive components 23, while the carrier structure 50 may be optionally arranged with at least one electronic component (not shown) thereon. Alternatively, as shown in FIG. 5B, the first surface 25a of the plurality of antenna structures 25 having the shielding body 26 is mounted onto the carrier structure 50 of a package module 5a having a plurality of electronic components 21 via a plurality of conductive components 23, while the electronic components 21 and the antenna structure 25 are arranged on each of the opposing sides of the carrier structure 50, respectively. As yet another alternative, as shown in FIG. 5C, the first surface 25a of the plurality of antenna structures 25 having the shielding body 26 is provided on an encapsulation layer 52 of a package module 5b having a plurality of electronic components 21, where the encapsulation layer 52 is buried with a plurality of conductive pillars 53 that electrically connected to the carrier structure 50, and the conductive pillars 53 are exposed from the encapsulation layer 52, such that the antenna structure 25 is electrically coupled with the conductive pillars 53 via the plurality of conductive components 23, and electrically connected to the carrier structure 50.

The present disclosure also provides an electronic package 2, 3, which comprises: a carrier structure 20, 50, at least one electronic component 21, an antenna structure 25 and at least one shielding body 26.

The electronic component 21 is provided on the carrier structure 20, 50 and electrically connected to the carrier structure 20, 50.

The antenna structure 25 is connected to the carrier structure 20, 50, and edges of the antenna structure 25 are formed with a stepped portion 251, 351.

The shielding body 26 is arranged along a surface of the stepped portion 251, 351 only and free from covering the whole side surface 25c of the antenna structure 25.

In an embodiment, the carrier structure 20, 50 is coupled to the antenna structure 25 via a plurality of conductive components 23.

In an embodiment, the antenna structure 25 comprises a first surface 25a, a second surface 25b opposite to the first surface 25a, and side surfaces 25c abutting the first and second surface 25a, 25b, and the first surface 25a of the antenna structure 25 is connected to the carrier structure 20, 50. For example, the stepped portion 251 is formed at the interface between the first surface 25a and the side surface 25c. Alternatively, the stepped portion 351 is formed at the interface between the second surface 25b and the side surface 25c.

In an embodiment, the electronic package 2, 3 further comprises encapsulation layer 22, 29, 52 that encapsulates the electronic component 21. For example, a shielding layer 24 is formed on the encapsulation layer 22, 29.

In an embodiment, the shielding body 26 is a metal layer.

In summary, the electronic package and the manufacturing method thereof according to the present disclosure utilize the design of the stepped portion to enable the shielding body to cover a part of the side surface of the antenna structure only so as to prevent the shielding body from shielding the antenna structure. Therefore, the electronic package according to the present disclosure may effectively operate the antenna functionality of the antenna structure.

The above embodiments are set forth to illustrate the principles of the present disclosure, and should not be interpreted as to limit the present disclosure in any way. The above embodiments can be modified by one of ordinary skill in the art without departing from the scope of the present disclosure as defined in the appended claims.

What is claimed is:

1. An electronic package, comprising:
a carrier structure;
an electronic component disposed on the carrier structure;
an antenna structure mounted on the carrier structure, wherein the antenna structure has an edge formed with a stepped portion; and
a shielding body arranged along a surface of the stepped portion.

2. The electronic package of claim 1, wherein the carrier structure is coupled to the antenna structure via a plurality of conductive components.

3. The electronic package of claim 1, wherein the antenna structure has a first surface, a second surface opposite to the first surface, and a side surface abutting the first and second surfaces, and wherein the first surface of the antenna structure is connected to the carrier structure.

4. The electronic package of claim 3, wherein the stepped portion is formed at an interface between the first surface and the side surface.

5. The electronic package of claim 3, wherein the stepped portion is formed at an interface between the second surface and the side surface.

6. The electronic package of claim 1, further comprising an encapsulation layer encapsulating the electronic component.

7. The electronic package of claim 6, further comprising a shielding layer formed on the encapsulation layer.

8. A method for manufacturing an electronic package, comprising:
providing at least one package module, wherein the package module comprises a carrier structure and an electronic component disposed on the carrier structure; and
connecting an antenna structure to the carrier structure, wherein the antenna structure has an edge formed with a stepped portion, and wherein a shielding body is arranged on a surface of the stepped portion.

9. The method of claim 8, wherein the carrier structure is coupled to the antenna structure via a plurality of conductive components.

10. The method of claim 8, wherein the antenna structure has a first surface, a second surface opposite to the first surface, and a side surface abutting the first and second surfaces, and wherein the first surface of the antenna structure is connected to the carrier structure.

11. The method of claim 10, wherein the stepped portion is formed at an interface between the first surface and the side surface.

12. The method of claim 10, wherein the stepped portion is formed at an interface between the second surface and the side surface.

13. The method of claim 8, further comprising encapsulating the electronic component via an encapsulation layer.

14. The method of claim 13, further comprising forming a shielding layer on the encapsulation layer.
